(19) United States
(12) Patent Application Publication
(10) Pub. No.: US 2026/0293398 A1
(43) Pub. Date: Sep. 24, 2026

(54) DISPLAY PANEL

(71) Applicant: AUO Corporation, Hsinchu City (TW)

(72) Inventors: Jeng-Hua Tsai, Hsinchu City (TW); Yu-Cheng Chang, Hsinchu City (TW); Po Han Lin, Hsinchu City (TW); Zhuo-Ren Lang, Hsinchu City (TW)

(73) Assignee: AUO Corporation, Hsinchu City (TW)

(21) Appl. No.: 19/330,814

(22) Filed: Sep. 16, 2025

(30) Foreign Application Priority Data
Mar. 20, 2025 (TW) 114110495

(51) Int. Cl. H10H 29/41; H10H 29/49; H10H 29/85; H10W 90/00

(52) U.S. Cl. CPC H10H 29/41; H10H 29/49; H10H 29/8582; H10W 90/00

(57) ABSTRACT

A display panel includes a substrate, pixels disposed on the substrate, and an insulating layer disposed on the substrate. Each of the pixels includes pixel driving circuits, pad groups and light emitting elements. The pad groups are electrically connected to the pixel driving circuits respectively. The light emitting elements are respectively bonded to the pad groups. The insulating layer includes a first edge portion. The first edge portion of the insulating layer are located outside the pad groups of the pixels.

### CROSS-REFERENCE TO RELATED APPLICATION

This application claims the priority benefit of TW application serial no.114110495, filed on Mar. 20, 2025. The entirety of the above-mentioned patent application is hereby incorporated by reference herein and made a part of this specification.

### BACKGROUND

### Technical Field

The present disclosure relates to a display panel.

### Related Art

Light emitting diode display panels include an active component substrate and multiple light emitting diode components transferred onto the active component substrate. Inheriting the characteristics of light emitting diodes, light emitting diode display panels have advantages such as power saving, high efficiency, high brightness, and fast response time. In addition, compared to organic light emitting diode display panels, light emitting diode display panels also have advantages such as easy color calibration, long light emitting lifespan, and no image burn-in. Therefore, light emitting diode display panels are regarded as the next generation display technology.

In the manufacturing process of light emitting diode display panels, a laser bonding process may be used to bond multiple light emitting diode components on a light emitting component carrier with multiple pad groups of an active component substrate. However, the film layer edge of the active component substrate and the substrate surface of the active component substrate have a step difference. During the laser bonding process, the light emitting component carrier may be compressed along the step difference, and the light emitting component carrier may be softened by heat, resulting in serious offset issues between light emitting components and pad groups in the edge region.

### SUMMARY

The present disclosure provides a display panel with small offset between light emitting elements and pad groups in the edge region.

A display panel according to an embodiment of the present disclosure includes a substrate, multiple pixels disposed on the substrate, and an insulating layer disposed on the substrate. Each of the pixels includes pixel driving circuits, pad groups, and light emitting elements. The pad groups are respectively electrically connected to the pixel driving circuits. The light emitting elements are respectively bonded to the pad groups. The insulating layer includes a middle portion and a first edge portion. The middle portion and the first edge portion of the insulating layer are located outside the pad groups of the pixels. The first edge portion of the insulating layer is located between the middle portion of the insulating layer and the edge of the substrate. A surface roughness of the first edge portion of the insulating layer is greater than a surface roughness of the middle portion of the insulating layer.

A display panel according to an embodiment of the present disclosure includes a substrate, pixels disposed on the substrate, and an insulating layer disposed on the substrate. Each of the pixels includes pixel driving circuits, pad groups, and light emitting elements. The pad groups are respectively electrically connected to the pixel driving circuits. The light emitting elements are respectively bonded to the pad groups. The insulating layer includes a first edge portion. The first edge portion of the insulating layer is located outside the pad groups of the pixels. The first edge portion of the insulating layer has multiple first micro protrusions arranged at intervals. A first micro protrusions has a protrusion height ΔH1. There is a distance H1 between the top surface of the light emitting elements and the substrate. 5%≤(ΔH1/H1) ≤40%.

### BRIEF DESCRIPTION OF THE DRAWINGS

FIG. 1 is a top view schematic diagram of a spliced display device according to an embodiment of the present disclosure.

FIG. 2 is a top view and magnified schematic diagram of a display panel according to an embodiment of the present disclosure.

FIG. 3 is a cross-sectional schematic diagram of a display panel according to an embodiment of the present disclosure.

FIG. 4 is a top view and magnified schematic diagram of a display panel according to an embodiment of the present disclosure.

FIG. 5 is a cross-sectional schematic diagram of a display panel according to an embodiment of the present disclosure.

FIG. 6 is a cross-sectional schematic diagram of a display panel according to an embodiment of the present disclosure.

FIG. 7 is a top view and magnified schematic diagram of a display panel according to another embodiment of the present disclosure.

FIG. 8 is a cross-sectional schematic diagram of a display panel according to another embodiment of the present disclosure.

FIG. 9 is a top view and magnified schematic diagram of a display panel according to yet another embodiment of the present disclosure.

FIG. 10 is a cross-sectional schematic diagram of a display panel according to yet another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the disclosure and will not be interpreted in an idealized or overly formal sense unless expressly so defined herein.

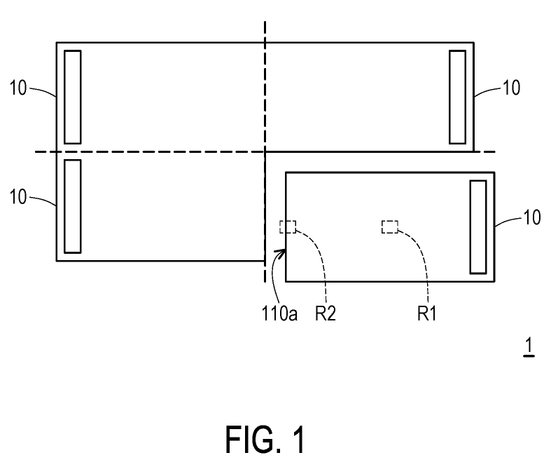

FIG. 1 is a top view schematic diagram of a spliced display device according to an embodiment of the present disclosure. Referring to FIG. 1, the spliced display device 1 includes multiple display panels 10. The multiple display panels 10 are spliced together to provide a large display screen. Each of the display panel 10 has at least one edge 110a that is spliced with other display panels 10.

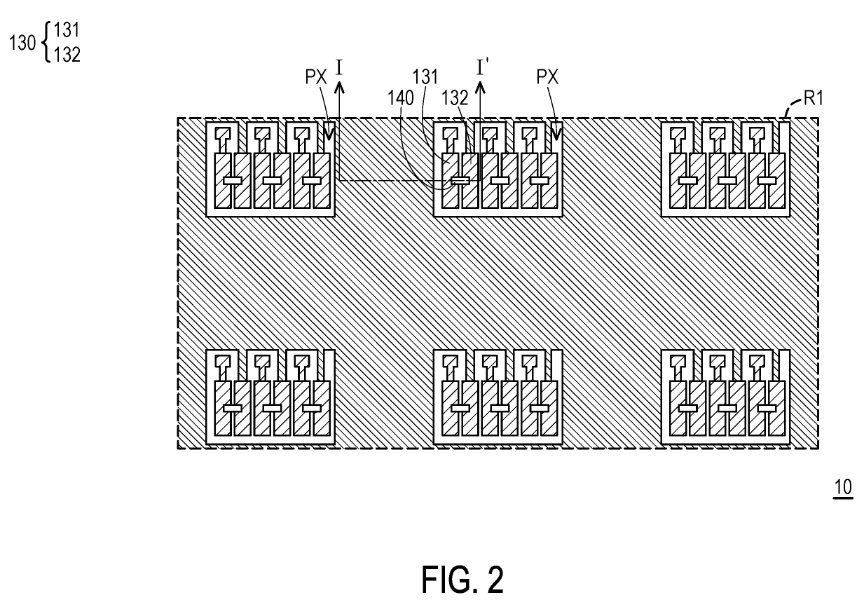

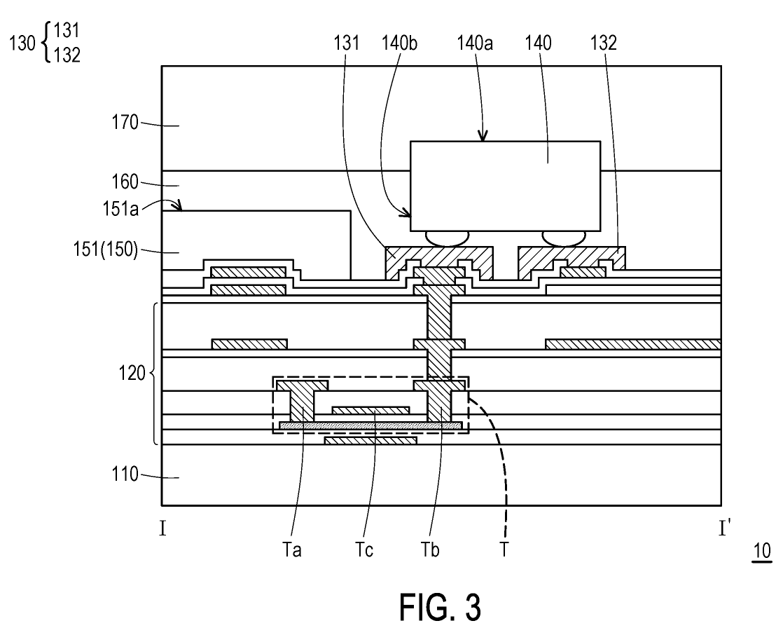

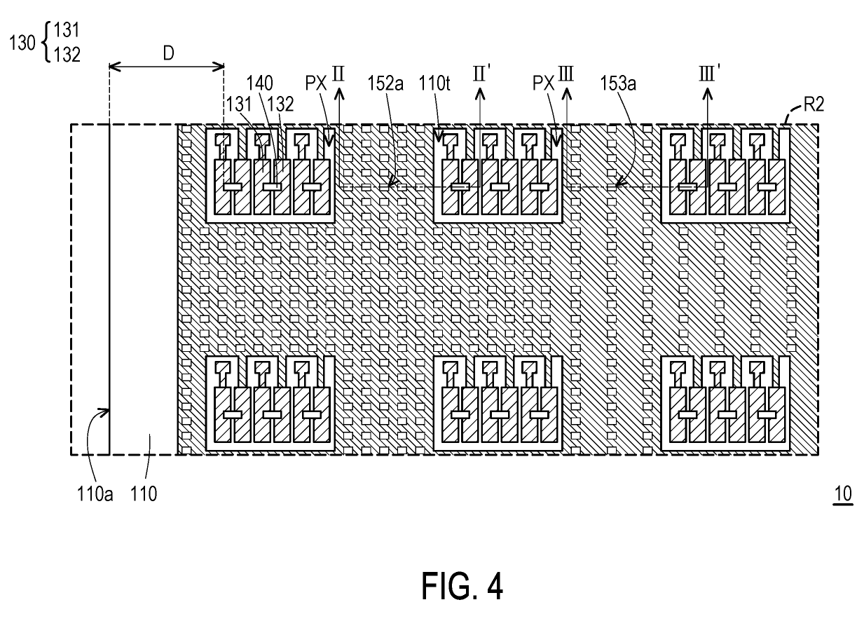

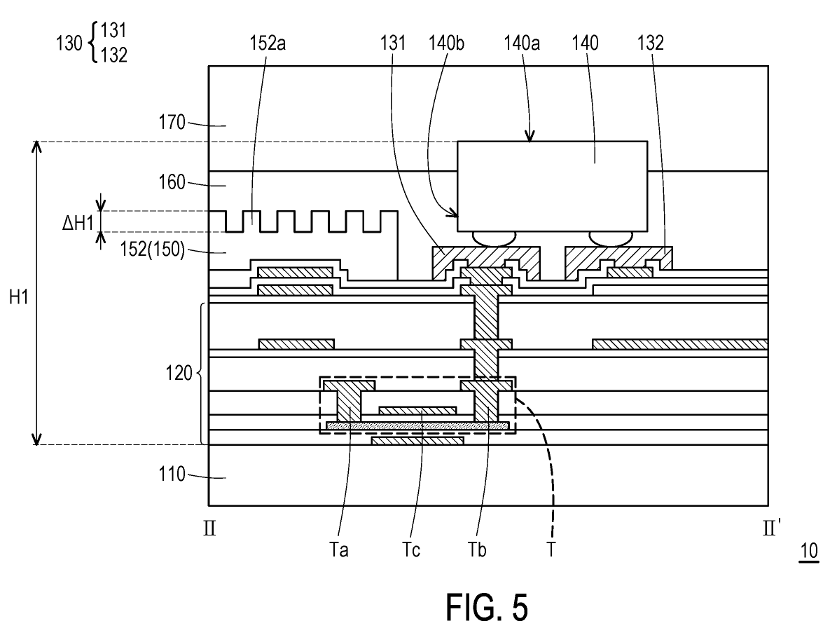

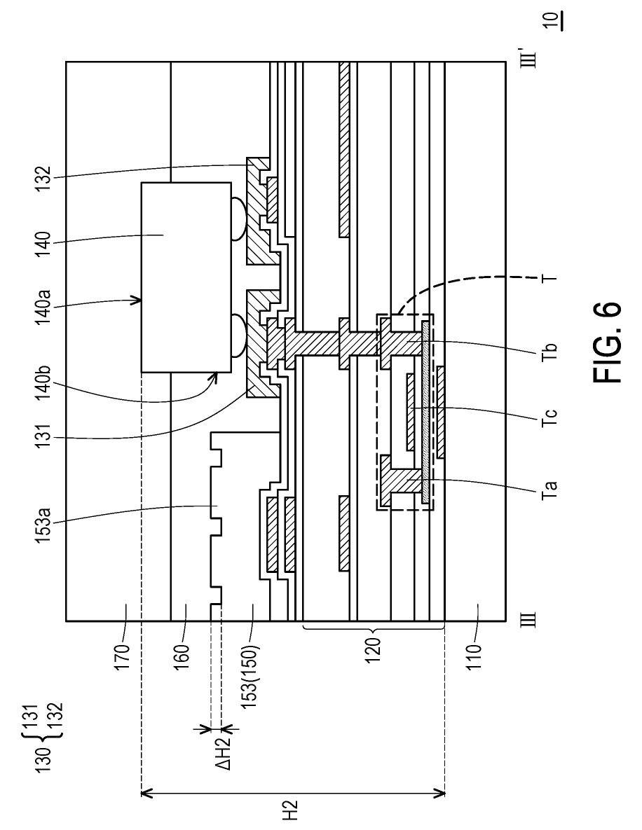

FIG. 2 is a top view and magnified schematic diagram of a display panel according to an embodiment of the present disclosure. FIG. 2 corresponds to the middle region R1 of one display panel 10 in FIG. 1. FIG. 3 is a cross-sectional schematic diagram of a display panel according to an embodiment of the present disclosure. FIG. 3 corresponds to the cross-section line I-I' in FIG. 2. FIG. 4 is a top view and magnified schematic diagram of a display panel according to an embodiment of the present disclosure. FIG. 4 corresponds to the edge region R2 of one display panel 10 in FIG. 1. The edge region R2 has at least one edge 110a of the display panel 10. FIG. 5 is a cross-sectional schematic diagram of a display panel according to an embodiment of the present disclosure. FIG. 5 corresponds to the cross-section line II-II' in FIG. 4. FIG. 6 is a cross-sectional schematic diagram of a display panel according to an embodiment of the present disclosure. FIG. 6 corresponds to the cross-section line III-III' in FIG. 4.

Referring to FIGS. 2, 3, 4, 5, and 6, the display panel 10 includes a substrate 110 and multiple pixels PX disposed on the substrate 110. In some embodiments, the material of the substrate 110 may be glass, quartz, organic polymer, or opaque/reflective material (for example: wafer, ceramic, or other applicable materials), or other applicable materials.

Each of the pixels PX includes multiple pixel driving circuits 120, multiple pad groups 130 respectively electrically connected to the multiple pixel driving circuits 120, and multiple light emitting elements 140 respectively bonded to the multiple pad groups 130. For example, in some embodiments, each of the pixels PX may selectively include three pixel driving circuits 120, three pad groups 130 respectively electrically connected to the three pixel driving circuits 120, and three light emitting elements 140 respectively bonded to the three pad groups 130, wherein the three light emitting elements 140 are respectively used to emit first colored light, second colored light, and third colored light which are different from each other. In some embodiments, the first colored light, second colored light, and third colored light are, for example, red light, green light, and blue light respectively, but the present disclosure is not limited thereto.

In some embodiments, each of the pixel driving circuits 120 may selectively include a first transistor (not shown), a second transistor T, and a capacitor (not shown), wherein a first terminal of the first transistor is electrically connected to a corresponding data line (not shown), a control terminal of the first transistor is electrically connected to a corresponding scan line (not shown), a second terminal of the first transistor is electrically connected to a control terminal Tc of the second transistor T, a first terminal Ta of the second transistor T is electrically connected to a corresponding power line (not shown), the capacitor is electrically connected between the second terminal of the first transistor and the first terminal Ta of the second transistor T, and a second terminal Tb of the second transistor T is electrically connected to a corresponding pad group 130. In brief, in some embodiments, each of the pixel driving circuit 120 may selectively have a 2T1C architecture. However, the present disclosure is not limited thereto, and in other embodiments, the pixel driving circuit 120 may also have other architectures.

In some embodiments, each of the pad groups 130 may selectively include a first pad 131 and a second pad 132, wherein the first pad 131 is electrically connected to a corresponding pixel driving circuit 120, the second pad 132 is electrically connected to a corresponding common line (not shown), and two electrodes of a light emitting element 140 are respectively bonded to the first pad 131 and the second pad 132. In some embodiments, the light emitting element 140 may be a flip chip type and bonded to the first pad 131 and the second pad 132 of the corresponding same pad group 130. However, the present disclosure is not limited thereto, and in other embodiments, the light emitting element 140 may also be other types, for example: vertical type, lateral type, etc.

The display panel 10 further includes an insulating layer 150 disposed on the substrate 110. In some embodiments, the insulating layer 150 is located on the pixel driving circuit 120, and the pixel driving circuit 120 is located between the insulating layer 150 and the substrate 110. The insulating layer 150 may be a single film layer or a stacked structure of multiple film layers. In some embodiments, the material of the insulating layer 150 may be an inorganic material (for example: silicon oxide, silicon nitride, silicon oxynitride, or a stacked layer of at least two of the aforementioned materials), an organic material, or a combination thereof.

In some embodiments, the display panel 10 further includes a molding layer 160 disposed on the insulating layer 150 and at least covering the sidewall 140b of the light emitting element 140. In some embodiments, the insulating layer 150 contacts the molding layer 160. In some embodiments, the display panel 10 may selectively further include a waterproof layer 170 disposed on the molding layer 160 and covering the top surface 140a of the light emitting element 140, but the present disclosure is not limited thereto.

Referring to FIGS. 1, 2, 3, 4, and 5, the insulating layer 150 includes a middle portion 151 (marked in FIG. 3) and a first edge portion 152 (marked in FIG. 5). The middle portion 151 and the first edge portion 152 of the insulating layer 150 are located outside the pad groups 130 of the pixels PX. The first edge portion 152 of the insulating layer 150 is located between the middle portion 151 of the insulating layer 150 and the edge 110a of the substrate 110.

It is worth noting that the surface roughness of the first edge portion 152 of the insulating layer 150 is greater than the surface roughness of the middle portion 151 of the insulating layer 150. When the multiple light emitting elements 140 on a light emitting element carrier (not shown) are bonded to the multiple pad groups 130 using a laser bonding process, although the light emitting element carrier may be heated and softened due to laser irradiation, since the surface roughness of the first edge portion 152 of the insulating layer 150 is relatively large, the light emitting elements 140 on the softened light emitting element carrier are not likely to significantly offset from the pad groups 130. The offset issue between the light emitting elements 140 and the pad groups 130 that tends to occur in the edge region R2 may be improved. When the offset between the light emitting elements 140 and the pad groups 130 may be well controlled and relatively small, the distance D (marked in FIG. 4) between the light emitting elements 140 and the edge 110a of the substrate 110 may be designed to be smaller, which helps reducing the width of the splicing seam of the splicing display device 1.

In some embodiments, the center wavelength of the laser used in the aforementioned laser bonding process may fall within a range of 400nm to 1200nm, and the absorption rate of the insulating layer 150 for the laser is less than 1%. That is, under the laser irradiation, the surface temperature of the insulating layer 150 is low, which helps reducing the degree of heating and softening of the light emitting element carrier due to laser irradiation, thereby the offset issue between the light emitting elements 140 and the pad groups 130 can be improved. In some embodiments, the thermal conductivity of the insulating layer 150 is less than 10W/m•K. That is, under the laser irradiation, the thermal conduction speed of the insulating layer 150 is slow, which helps reducing the degree of heating and softening of the light emitting element carrier due to laser irradiation, thereby the offset issue between the light emitting elements 140 and the pad groups 130 can be improved. In some embodiments, the wavelength of visible light falls within a range of 380nm to 780nm, and the transmittance of the insulating layer 150 for visible light is greater than 99%. That is, the provision of the insulating layer 150 hardly affects the transparency of the display panel 10.

Referring to FIGS. 1, 2, 3, 4, and 5, in some embodiments, the first edge portion 152 of the insulating layer 150 has first micro protrusions 152a arranged at intervals (marked in FIGS. 4 and 5), and the middle portion 151 of the insulating layer 150 has a flat surface 151a (marked in FIG. 3). In some embodiments, the range with the first micro protrusions 152a may extend inward from the edge 110a of the substrate 110 by approximately 2 mm, or in other words, 2 to 4 pixels PX inward from the edge 110a of the substrate 110, but the present disclosure is not limited thereto. In some embodiments, the first edge portion 152 of the insulating layer 150 having the first micro protrusions 152a is formed by using a grayscale mask, for example, but the present disclosure is not limited thereto. The multiple first micro protrusions 152a and multiple recesses between the multiple first micro protrusions 152a may form a first uneven structure. In some embodiments, the first uneven structure may be formed by etching downward from an original film layer, or by adding an additional film layer.

Referring to FIGS. 1, 4, 5, and 6, in some embodiments, the insulating layer 150 further includes a second edge portion 153 (marked in FIG. 6), and the second edge portion 153 of the insulating layer 150 is located outside the multiple pad groups 130 of the multiple pixels PX. Referring to FIGS. 1, 2, 3, 4, 5, and 6, the second edge portion 153 of the insulating layer 150 is located between the middle portion 151 of the insulating layer 150 and the first edge portion 152 of the insulating layer 150. Both of the first edge portion 152 and the second edge portion 153 are located in the edge region R2 of the display panel 10, and the second edge portion 153 is farther from the edge 110a of the substrate 110 than the first edge portion 152. The surface roughness of the second edge portion 153 of the insulating layer 150 is between the surface roughness of the middle portion 151 of the insulating layer 150 and the surface roughness of the first edge portion 152 of the insulating layer 150.

Referring to FIGS. 4, 5, and 6, in some embodiments, the first edge portion 152 of the insulating layer 150 has first micro protrusions 152a arranged at intervals, the second edge portion 153 of the insulating layer 150 has multiple second micro protrusions 153a arranged at intervals, and the protrusion height (or in other words, step difference) ΔH1 of the first micro protrusions 152a is greater than the protrusion height (or in other words, step difference) ΔH2 of the second micro protrusions 153a. That is to say, in the edge region R2 of the display panel 10, the closer to the edge 110a of the substrate 110, the higher the protrusion height of the micro protrusions of the insulating layer 150, and the greater the surface roughness of the insulating layer 150. Thereby, it helps further improving the issue of offset between the light emitting elements 140 and the pad groups 130 that becomes more severe closer to the edge 110a.

The multiple second micro protrusions 153a and the multiple recesses between the multiple second micro protrusions 153a may form a second uneven structure. In some embodiments, the second uneven structure may be formed by etching downward into an original film layer, or may be fabricated by adding an additional film layer.

Referring to FIGS. 4 and 5, in some embodiments, the first edge portion 152 of the insulating layer 150 has multiple first micro protrusions 152a arranged at intervals, the first micro protrusion 152a has a protrusion height ΔH1, there is a distance H1 between the top surface 140a of the light emitting element 140 and the substrate 110, and 5%≤(ΔH1/H1) ≤40%. (ΔH1/H1) falling within the aforementioned range may make the arrangement of the first micro protrusions 152a less likely to affect other designs of the display panel 10. In addition, (ΔH1/H1) falling within the aforementioned range may also make the molding layer 160 still have good stability after removing the waterproof layer 170 (or waterproof adhesive). Referring to FIG. 5, in this embodiment, ΔH1 falls within a range of 0.15μm~3μm, for example, but the present disclosure is not limited thereto. Referring to FIGS. 4 and 6, in some embodiments, the second edge portion 153 of the insulating layer 150 has multiple second micro protrusions 153a arranged at intervals, the second micro protrusions 153a have a protrusion height ΔH2, there is a distance H2 between the top surface 140a of the light emitting element 140 and the substrate 110, and 5%≤(ΔH2/H2) ≤40%. (ΔH2/H2) falling within the aforementioned range may make the arrangement of the second micro protrusions 153a less likely to affect other designs of the display panel 10. In addition, (ΔH2/H2) falling within the aforementioned range may also make the molding layer 160 still have good stability after removing the waterproof layer 170 (or waterproof adhesive).

Referring to FIGS. 4, 5 and 6, in some embodiments, the distribution density of the multiple first micro protrusions 152a is greater than the distribution density of the multiple second micro protrusions 153a. That is, in some embodiments, in the edge region R2 of the display panel 10, the closer to the edge 110a of the substrate 110, the greater the distribution density of the micro protrusions of the insulating layer 150. Thereby, it helps further improving the issue of offset between the light emitting element 140 and the pad group 130 that becomes more severe closer to the edge 110a.

It must be noted here that the following embodiments use the same component reference numbers and partial content as the aforementioned embodiments, wherein the same reference numbers are used to represent the same or similar components, and descriptions of the same technical content are omitted. For descriptions of the omitted parts, reference may be made to the aforementioned embodiments, and the following embodiments will not repeat them.

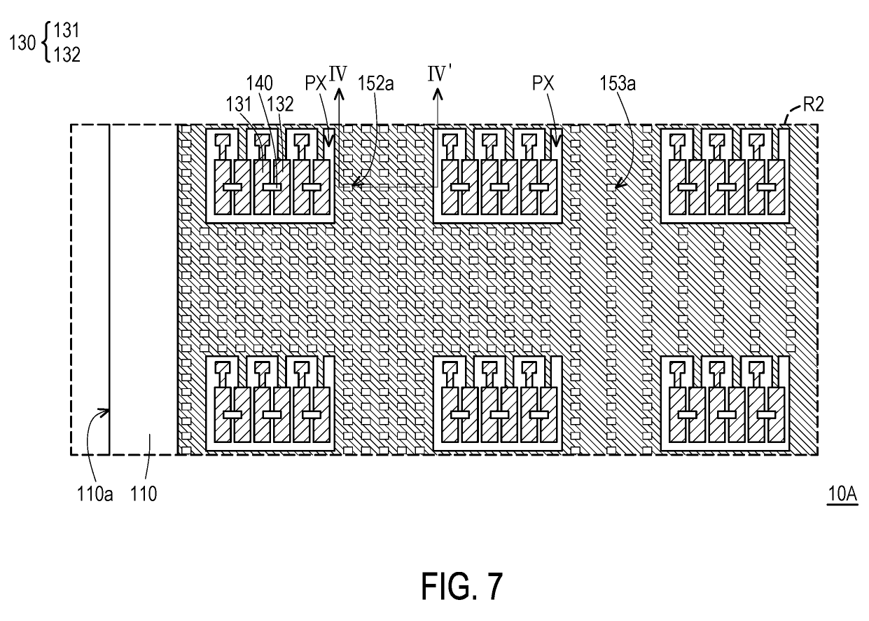

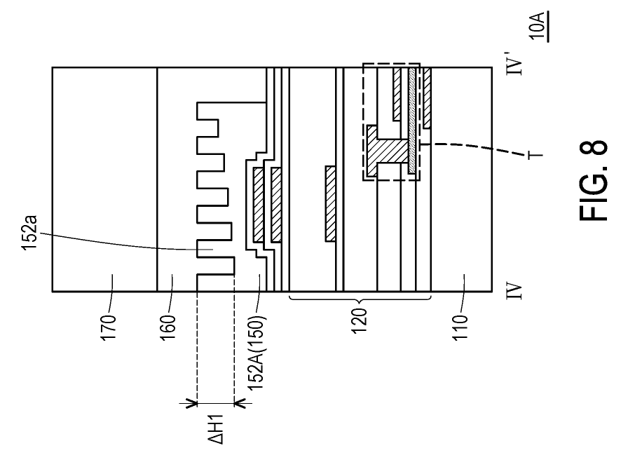

FIG. 7 is a top view and magnified schematic diagram of a display panel according to another embodiment of the present disclosure. FIG. 8 is a cross-sectional schematic diagram of a display panel according to another embodiment of the present disclosure. FIG. 8 corresponds to the cross-section line IV-IV' of FIG. 7.

The display panel 10A of FIGS. 7 and 8 is similar to the aforementioned display panel 10, and the difference between them is that: the first edge portion 152A of the insulating layer 150 of the display panel 10A of FIGS. 7 and 8 is different from the first edge portion 152 of the insulating layer 150 of the aforementioned display panel 10. Referring to FIGS. 7 and 8, specifically, in this embodiment, the first edge portion 152A of the insulating layer 150 has multiple first micro protrusions 152a that are spaced apart, and the multiple protrusion heights ΔH1 of the multiple first micro protrusions 152a gradually increase as they approach the edge 110a of the substrate 110.

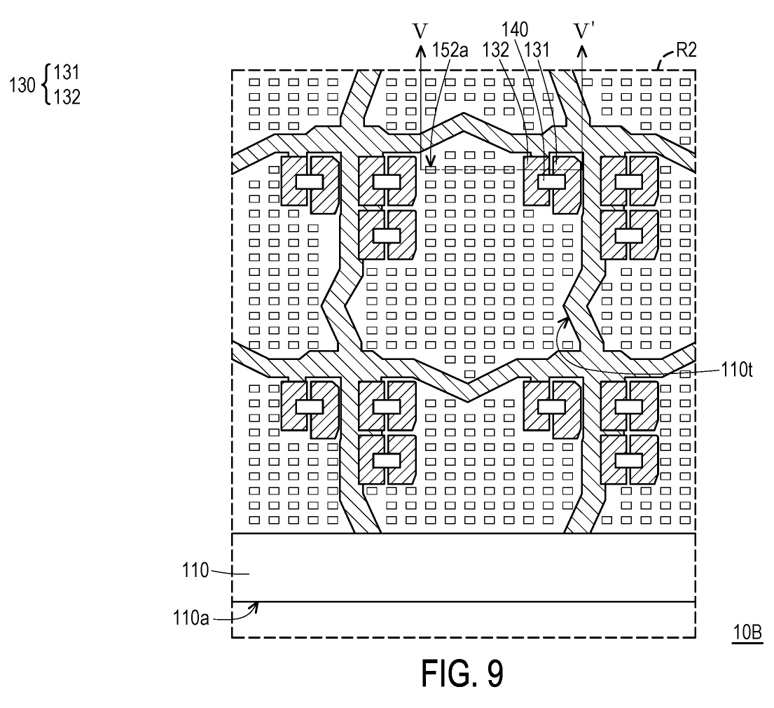

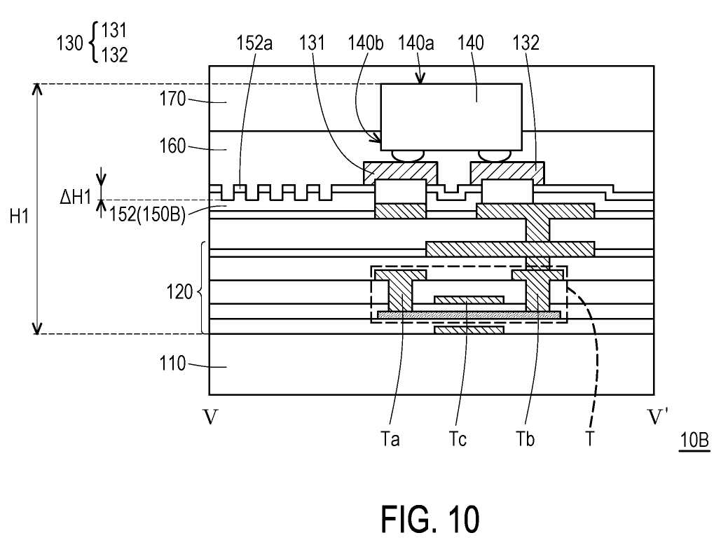

FIG. 9 is a top view and magnified schematic diagram of a display panel according to yet another embodiment of the present disclosure. FIG. 10 is a cross-sectional schematic diagram of a display panel according to yet another embodiment of the present disclosure. FIG. 10 corresponds to the cross-section line V-V' of FIG. 9. The display panel 10B of FIGS. 9 and 10 is similar to the aforementioned display panel 10, and the difference between them is that: the aforementioned display panel 10 has no transmissive region 110t between the multiple pixels PX or the area ratio of the transmissive region 110t is very small, as shown in FIG. 4, the aforementioned display panel 10 is substantially a non-transparent display panel, and the molding layer 160 of the aforementioned display panel 10 may absorb light; there is a sufficiently large transmissive region 110t between the multiple pixels PX of the display panel 10B of FIGS. 9 and 10, the display panel 10B is a transparent display panel, and the molding layer 160 of the display panel 10B may be transmissive.

Furthermore, as shown in FIG. 5, in the aforementioned display panel 10B, the insulating layer 150 and the pad group 130 are substantially located on the same plane; as shown in FIG. 10, in the display panel 10B of this embodiment, the insulating layer 150 may be slightly lower than the pad group 130. Moreover, referring to FIG. 10, in this embodiment, the first edge portion 152 of the insulating layer 150 has multiple first micro protrusions 152a that are spaced apart, the first micro protrusion 152a has a protrusion height ΔH1, there is a distance H1 between the top surface 140a of the light emitting element 140 and the substrate 110, and 5%≤(ΔH1/H1) ≤40%. Referring to FIG. 10, in this embodiment, ΔH1 falls within a range of 0.5μm~3μm, for example, but the present disclosure is not limited thereto.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display panel, comprising:
a substrate;
a plurality of pixels disposed on the substrate, wherein each of the pixels comprises:
a plurality of pixel driving circuits;
a plurality of pad groups electrically connected to the pixel driving circuits respectively; and
a plurality of light emitting elements bonded to the pad groups respectively; and
an insulating layer disposed on the substrate;
the insulating layer comprises a middle portion and a first edge portion, the middle portion and the first edge portion of the insulating layer is located outside the pad groups of the pixels, the first edge portion of the insulating layer is located between the middle portion of the insulating layer and an edge of the substrate, wherein a surface roughness of the first edge portion of the insulating layer is greater than a surface roughness of the middle portion of the insulating layer.

2. The display panel as claimed in claim 1, wherein the first edge portion of the insulating layer has a plurality of first micro protrusions disposed at intervals, and the middle portion of the insulating layer has a flat surface.

3. The display panel as claimed in claim 1, wherein the first edge portion of the insulating layer has a plurality of first micro protrusions disposed at intervals, and a plurality of protrusion heights of the first micro protrusions gradually increase as approaching the edge of the substrate.

4. The display panel as claimed in claim 1, wherein the insulating layer further comprises a second edge portion, the second edge portion of the insulating layer is located outside the pad groups of the pixels, the second edge portion of the insulating layer is located between the middle portion of the insulating layer and the first edge portion of the insulating layer, wherein a surface roughness of the second edge portion of the insulating layer is between the surface roughness of the middle portion of the insulating layer and the surface roughness of the first edge portion of the insulating layer.

5. The display panel as claimed in claim 1, wherein the insulating layer further comprises a second edge portion, the second edge portion of the insulating layer is located outside the pad groups of the pixels, the second edge portion of the insulating layer is located between the middle portion of the insulating layer and the first edge portion of the insulating layer, the first edge portion of the insulating layer has a plurality of first micro protrusions disposed at intervals, the second edge portion of the insulating layer has a plurality of second micro protrusions disposed at intervals, and a protrusion height of one of the first micro protrusions is greater than a protrusion height of one of the second micro protrusions.

6. The display panel as claimed in claim 1, wherein the insulating layer further comprises a second edge portion, the second edge portion of the insulating layer is located outside the pad groups of the pixels, the second edge portion of the insulating layer is located between the middle portion of the insulating layer and the first edge portion of the insulating layer, the first edge portion of the insulating layer has a plurality of first micro protrusions disposed at intervals, the second edge portion of the insulating layer has a plurality of second micro protrusions disposed at intervals, and a distribution density of the first micro protrusions is greater than a distribution density of the second micro protrusions.

7. The display panel as claimed in claim 1, wherein the first edge portion of the insulating layer has a plurality of first micro protrusions disposed at intervals, one of the first micro protrusions has a protrusion height, the protrusion height is ΔH1, there is a distance between a top surface of one of the light emitting elements and the substrate, the distance is H1, and 5%≤(ΔH1/H1) ≤40%.

8. The display panel as claimed in claim 1, wherein a center wavelength of a laser falls within a range of 400nm~1200nm, and an absorption rate of the insulating layer to the laser is less than 1%.

9. The display panel as claimed in claim 1, wherein a wavelength of a visible light falls within a range of 380nm~780nm, and a transmittance of the insulating layer to the visible light is greater than 99%.

10. The display panel as claimed in claim 1, wherein a thermal conductivity of the insulating layer is less than 10W/m‧K.

11. A display panel, comprising:
a substrate;
a plurality of pixels disposed on the substrate, wherein each of the pixels comprises:
a plurality of pixel driving circuits;
a plurality of pad groups respectively electrically connected to the pixel driving circuits; and
a plurality of light emitting elements respectively bonded to the pad groups; and
an insulating layer disposed on the substrate, wherein the insulating layer comprises a first edge portion, the first edge portion of the insulating layer is located outside the pad groups of the pixels, the first edge portion of the insulating layer has a plurality of first micro protrusions disposed at intervals, one of the first micro protrusions has a protrusion height, the protrusion height is ΔH1, there is a distance between a top surface of one of the light emitting elements and the substrate, and the distance is H1, and 5%≤(ΔH1/H1) ≤40%.

12. The display panel as claimed in claim 11, wherein a plurality of protrusion heights of the first micro protrusions gradually increase as approaching an edge of the substrate.

13. The display panel as claimed in claim 11, wherein the insulating layer further comprises a second edge portion, the second edge portion of the insulating layer is located outside the pad groups of the pixels, the first edge portion of the insulating layer is located between the second edge portion of the insulating layer and an edge of the substrate, the second edge portion of the insulating layer has a plurality of second micro protrusions disposed at intervals, and a protrusion height of one of the first micro protrusions is greater than a protrusion height of one of the second micro protrusions.

14. The display panel as claimed in claim 11, wherein the insulating layer further comprises a second edge portion, the second edge portion of the insulating layer is located outside the pad groups of the pixels, the first edge portion of the insulating layer is located between the second edge portion of the insulating layer and an edge of the substrate, the second edge portion of the insulating layer has a plurality of second micro protrusions disposed at intervals, and a distribution density of the first micro protrusions is greater than a distribution density of the second micro protrusions.

15. The display panel as claimed in claim 12, wherein a center wavelength of a laser falls within a range of 400nm~1200nm, and an absorption rate of the insulating layer to the laser is less than 1%.

16. The display panel as claimed in claim 11, wherein a wavelength of a visible light falls within a range of 380nm~780nm, and a transmittance of the insulating layer to the visible light is greater than 99%.

17. The display panel as claimed in claim 11, wherein a thermal conductivity of the insulating layer is less than 10W/m•K.
